(19) United States
(12) Patent Application Publication
(10) Pub. No.: US 2026/0168822 A1
(43) Pub. Date: Jun. 18, 2026

(54) POSITION MEASUREMENT METHOD AND DEVICE

(71) Applicant: BRIGHTEST TECHNOLOGY TAIWAN CO., LTD., Hsinchu County (TW)

(72) Inventors: Kuo-Feng TSENG, Santa Clara, CA (US); Chengwei HSU, Hsinchu County (TW); Pei-Chi HUANG, Hsinchu County (TW); Zhonghua DONG, Santa Clara, CA (US); Jie ZHANG, Santa Clara, CA (US)

(21) Appl. No.: 18/983,683

(22) Filed: Dec. 17, 2024

(51) Int. Cl. G01D 5/26; G01R 31/26

(52) U.S. Cl. CPC G01D 5/266; G01R 31/2601; G01R 31/2648; G01D 2205/95

(57) ABSTRACT

A position measurement method includes: performing a calibration operation; and measuring a position of a stage according to a mapping table so as to control movement of the stage during an inspection operation. Performing the calibration operation includes: moving the stage along an axis; measuring N sets of first values, wherein each set of first values includes a first distance between a first mirror and a first laser interferometer and a second distance between the first mirror and a second laser interferometer; measuring N sets of second values, wherein each set of second values includes a third distance between a second mirror and a third laser interferometer and a fourth distance between the second mirror and a fourth laser interferometer; obtaining a flatness profile of the first mirror along the axis according to the first values and the second values; and generating the mapping table according to the flatness profile.

### TECHNICAL FIELD

The present application relates to a position measurement method and the associated device, particularly to a position measurement method and the associated device having an ability to calibrate nonlinearities in real-time.

### BACKGROUND

In modern semiconductor processing, an inspection procedure includes capturing a wafer's image for inspection. The position measurement device needs to be calibrated from time to time so as to minimize the nonlinearities and ensure the wafer can be moved to the desired position precisely for inspection. For example, the surface of optical elements in a position measurement device may deform due to temperature, repeating usage, or other non-ideal factors. When a flatness, a curvature, or a thickness of a mirror deviated from the design tolerance, the position measurement device may not obtain an accurate result.

However, as state-of-the-art, the position measurement device has to be removed from the wafer inspection system when the position measurement device needs the calibration. Because the position measurement device is not calibrated in real-time, the wafer inspection system cannot adaptively correct the varying nonlinearities. Furthermore, the removing and re-installing of the position measurement device cause long system down-time, and it is pricey to maintain the system to calibrate the position measurement device. Therefore, an effective means of calibrating position measurement device is critical in the field of wafer inspection.

### SUMMARY OF THE INVENTION

One aspect of the present disclosure provides a position measurement method configured to measure a position of a stage. The stage includes a first mirror and a second mirror. A first laser interferometer and a second laser interferometer face the first mirror along a first axis, and a third laser interferometer and a fourth laser interferometer face the second mirror along a second axis perpendicular to the first axis. The position measurement method includes: performing a calibration operation; and measuring the position of the stage according to a mapping table so as to control movement of the stage during an inspection operation. The step of performing the calibration operation includes: moving the stage along the second axis; measuring, by the first laser interferometer and the second laser interferometer, N sets of first values corresponding to N consecutive sections of the first mirror along the second axis as the stage moves, wherein an Mth set of first values comprises a first distance between the first mirror and the first laser interferometer and a second distance between the first mirror and the second laser interferometer; measuring, by the third laser interferometer and the fourth laser interferometer, N sets of second values as the N sets of first values are measured, wherein an Mth set of second values comprises a third distance between a second mirror and the third laser interferometer and a fourth distance between the second mirror and the fourth laser interferometer; obtaining a first flatness profile of the first mirror along the second axis according to the N sets of first values and the N sets of the second values, wherein N and M are a positive integer, and M is less or equal to N; and generating the mapping table according to the first flatness profile.

Compared to conventional technology, the position measurement device of the present application is able to in-situ calibrate the nonlinearities. Therefore, the cost and complexity of reducing the nonlinearities of the position measurement device can be optimized.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a schematic diagram of a position measurement device according to some embodiments of the present disclosure.

FIG. 2 is a schematic diagram of a stage according to some embodiments of the present disclosure.

FIG. 3, FIG. 4, FIG. 5, and FIG. 6 are schematic diagrams of nonlinearities of a position measurement device according to some embodiments of the present disclosure

FIG. 7 and FIG. 8 are flowcharts of a position measurement method according to some embodiments of the present disclosure.

FIG. 9 and FIG. 10 are schematic diagrams of position measurement operations according to some embodiments of the present disclosure.

FIG. 11 is a schematic diagram of a mapping table according to some embodiments of the present disclosure.

FIG. 12 and FIG. 13 are schematic diagrams of position measurement operations according to some embodiments of the present disclosure.

FIG. 14 and FIG. 15 are schematic diagrams of laser interferometers according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately,” or “about” generally mean within a value or range which can be contemplated by people having ordinary skill in the art. Alternatively, the terms “substantially,” “approximately,” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of times, temperatures, operating conditions, ratios of amounts, and the likes thereof disclosed herein, should be understood as modified in all instances by the terms “substantially,” “approximately,” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

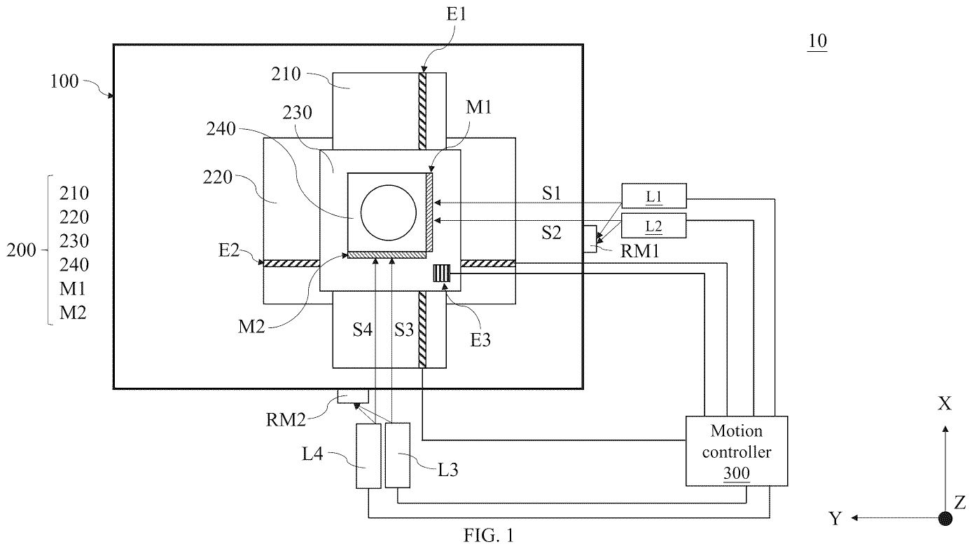

FIG. 1 is a schematic diagram of a position measurement device 10 according to some embodiments of the present disclosure. The position measurement device 10 is configured to measure and calibrate a position of a stage 200 when the stage 200 is moving in a platform 100. In some embodiments, the position measurement device 10 is implemented in a wafer inspection system, and configured to bear and control a movement of a wafer. However, the present disclosure is not limited to the wafer inspection system, the position measurement device 10 can be implemented in other system which needs moving and real-time position calibrating functions. To facilitate understanding, the position measurement device 10 is described as being implemented in a wafer inspection system in the present disclosure.

In some embodiments, the wafer inspection includes a calibration operation and an inspection operation. Before the inspection operation, the calibration operation is performed to calibrate nonlinearities of the position measurement device 10. In some embodiments, the nonlinearities may be caused by a Yaw rotation, a roll rotation, and a straightness of the stage 200. In addition, in some embodiments, mirrors that are used for detect the position of the stage 200 may not have fully flat surfaces, and such irregularities can cause to the nonlinearities as well.

These nonlinearities of the position measurement device 10 may have intrinsic amounts. The calibration operation is performed to calibrate these intrinsic amounts. However, these nonlinearities vary over time. Therefore, in some embodiments, during the inspection operation, the position measurement device 10 still calibrate the position of the stage 200 in real-time so as to optimize the accuracy of the position of the stage 200.

The position measurement device 10 includes the platform 100, the stage 200, a motion controller 300, a laser interferometer L1, a laser interferometer L2, a laser interferometer L3, a laser interferometer L4, an X encoder E1, a Y encoder E2, and a Z encoder E3.

The stage 200, the X encoder E1, the Y encoder E2, and the Z encoder E3 are disposed in the platform 100.

The motion controller 300 is configured to control a movement of stage 200 in the platform 100 using the X encoder E1, the Y encoder E2, and the Z encoder E3. The X encoder E1, the Y encoder E2, and the Z encoder E3 are configured to move the stage 200 along an X axis, a Y axis, and a Z axis, respectively. The X axis, the Y axis, and the Z axis are perpendicular to each other.

The stage 200 includes an X stage 210, a Y stage 220, a Z stage 230, a wafer holder 240, a mirror M1, and a mirror M2. The X stage 210, the Y stage 220, and the Z stage 230 are configured to move the wafer holder 240, and the wafer holder 240 is configured to bear the wafer under inspection. In some embodiments, the wafer holder 240 is an E-chuck. The X encoder E1, the Y encoder E2, and the Z encoder E3 are configured to control the movement of the X stage 210, the Y stage 220, and the Z stage 230, respectively.

The mirrors M1 and M2 are attached to the wafer holder 240. Each of the mirror M1 and the mirror M2 has a primary dimension (longitudinal dimension). The primary dimension of the mirror M1 is substantially parallel to the X axis, and the primary dimension of the mirror M2 is substantially parallel to the Y axis. The reflective surface of the mirror M1 faces the laser interferometers L1 and L2 along the Y axis, and the reflective surface of the mirror M2 faces the laser interferometers L3 and L4 along the X axis.

The laser interferometer L1 and the laser interferometer L2 are configured to measure a distance S1 between the reflective surface of the mirror M1 and the laser interferometers L1 and a distance S2 between the reflective surface of the mirror M1 and the laser interferometers L2. The laser interferometer L3 and the laser interferometer L4 are respectively configured to measure a distance S3 between the reflective surface of the mirror M2 and the laser interferometers L3 and a distance S4 between the reflective surface of the mirror M2 and the laser interferometers L4.

In the present embodiment, the position measurement device 10 further includes reference mirrors RM1 and RM2 that are attached on the platform 100. The reference mirror RM1 is disposed close to the laser interferometers L1 and L2 and configured as a reference point for the laser interferometers L1 and L2 to measure the distances S1 and S2. The reference mirror RM2 is disposed close to the laser interferometers L3 and L4 and configured as a reference point for the laser interferometers L3 and L4 to measure the distances S3 and S4.

In conventional arts, merely single laser interferometer is implemented in each direction to detection the position. However, in order to calibrate the above mentioned nonlinearities, a pair of laser interferometers are used in each direction in the present disclosure.

The motion controller 300 is further configured to calibrate the position of the stage 200 according to the distances S1−S4. In some embodiments, the moving controller 300 is further configured to control the movement of the stage 200 according to the calibrated position.

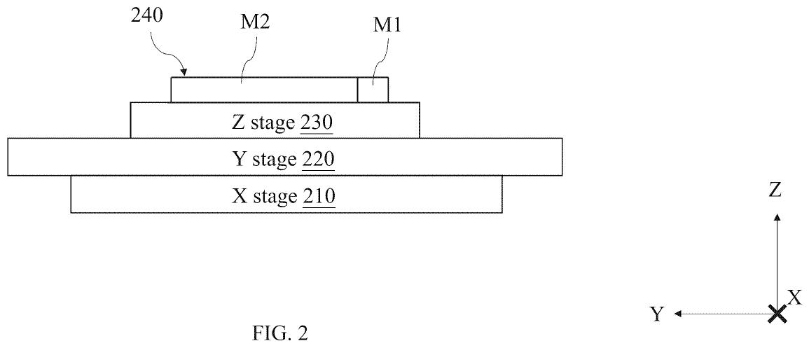

FIG. 2 is a schematic diagram of the stage 200 from a side view perspective according to some embodiments of the present disclosure. The Y stage 220 is disposed over the X stage 210. The Z stage 230 is disposed over the Y stage 220. The wafer holder 240 is disposed over the Z stage 230. In some embodiments, the arrangement of the X stage 210, the Y stage 220, and the Z stage 230 along the Z axis is not limited to the arrangement shown in FIG. 2. In various embodiments, the X stage 210, the Y stage 220, and the Z stage 230 can be switched with each other.

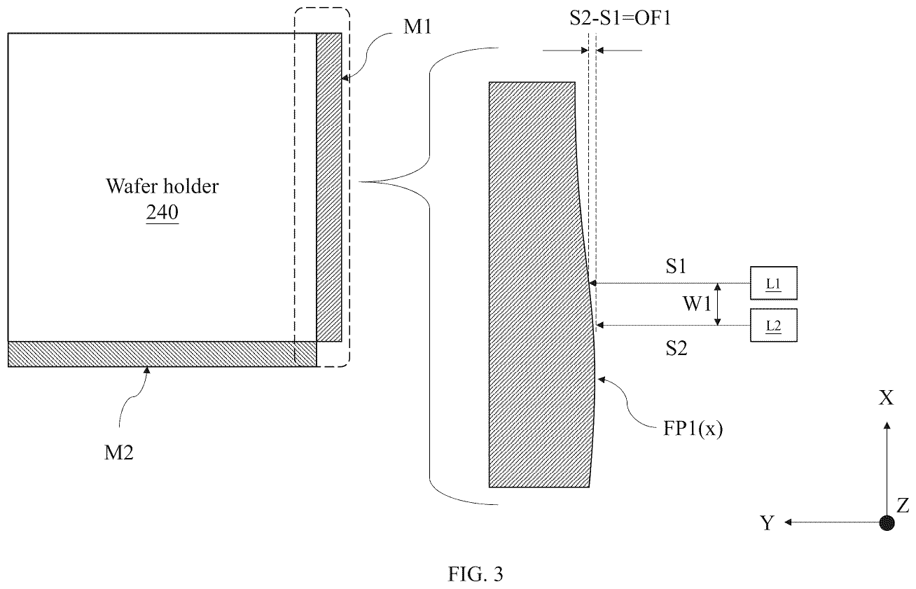

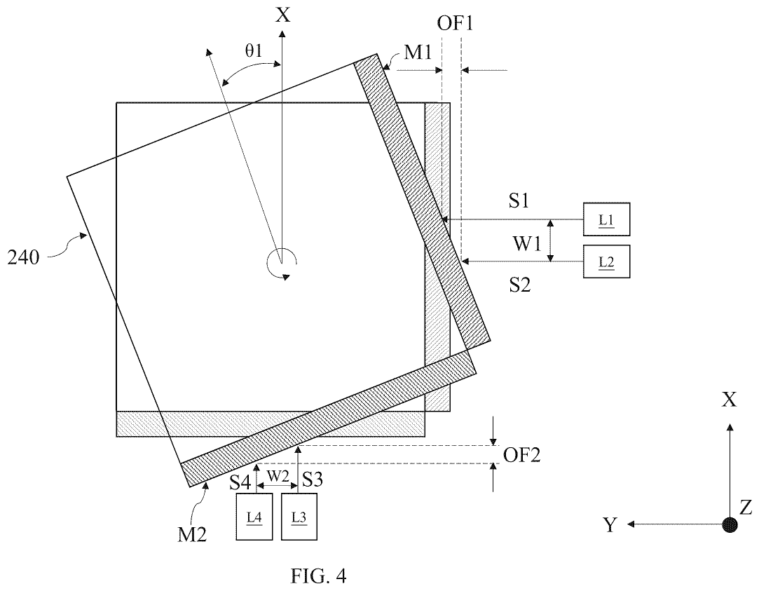

Please refer to FIG. 3, FIG. 4, FIG. 5, and FIG. 6. FIG. 3 to FIG. 6 are schematic diagrams of nonlinearities of the position measurement device 10 according to some embodiments of the present disclosure.

In some embodiments, the nonlinearities of the position measurement device 10 are contributed by the flatness (shown in FIG. 3) of the mirrors M1-M2 and the rotations of the stage 200, and the rotations of the stage 200 includes the Yaw rotation (shown in FIG. 4) and the roll rotation (shown in FIG. 5). Further, the nonlinearities of the position measurement device 10 also include the straightness (shown in FIG. 6).

In FIG. 3, the primary dimension of the mirror M1 is arranged along the X axis. Ideally, when the laser interferometers L1-L2 measure the distances S1−S2, the distance S1 should be equal to the distance S2. However, the reflective surface of the mirror M1 has a flatness greater than 0 due to some non-ideal factors, such as the manufacturing quality and the thermal expansion. The reflective surface of the mirror M1 is not a plane surface from a top view perspective, which results that the distance S1 is different from the distance S2. Because the flatness of the reflective surface of the mirror M1 varies along the primary dimension of the mirror M1, a numeral FP1(x) is designated to indicate a flatness profile of the mirror M1 over the X axis. Similarly, a numeral FP2(y) (not shown in FIG. 3) is designated to indicate a flatness profile of the mirror M2 over the Y axis.

An offset OF1 between the distance S2 and the distance S1 is denoted in FIG. 3. The offset OF1 includes a component of the flatness of the mirror M1. In some embodiments, if the flatness of the mirror M1 is the only factor that contributed to the nonlinearity, the offset OF1 is substantially equal to the nonlinearity of flatness.

In FIG. 4, when the stage 200 is moving along the X axis, the Yaw rotation is defined by a rotation around the Z axis. When the Yaw rotation occurs, the primary dimension of the mirror M1 has an included angle θ1 with respect to the X axis, and the component of the Yaw rotation in the offset OF1 can be represented as W1*θ1, in which a pitch W1 indicates a distance between the laser interferometer L1 and the laser interferometer L2 along the X axis. In some embodiments, when the nonlinearity is caused simply by the Yaw rotation, the offset OF1 is substantially equal to W1*θ1. It should be noted that the Yaw rotation can also be measured by the laser interferometers L3-L4. An offset OF2 between the distance S3 and the distance S4 can be represented as W2*θ1 when the nonlinearity only includes Yaw rotation, in which a pitch W2 is a pitch between the laser interferometers L3-L4. In some embodiments, the pitch W2 is equal to the pitch W1.

In FIG. 5, when the stage 200 is moving along the X axis, the roll rotation is defined by a rotation around the X axis. When the roll rotation occurs, an included angle θ2 between the Z axis and a normal vector of the stage 240 causes the mirror M1 deviates from the original level along the Z axis. However, the mirror M1 of its entirety has the same shift along the Y axis in the roll rotation. Therefore, the laser interferometer L1 and the laser interferometer L2 have the same shift to their measurement, and the offset OF1 does not include the component of the roll rotation. Similarly, the offset OF2 does not include the component of the roll rotation.

In FIG. 6, when the stage 200 is moving along the X axis, the straightness is defined by a distance perpendicular away from the X axis, namely, the straightness is parallel to the Y axis in this embodiment. Similar to the roll rotation, the mirror M1 of its entirety has the same shift along the Y axis in the straightness. Therefore, the offset OF1 does not include the component of the straightness. Regarding the laser interferometers L3-L4, since the straightness is parallel to the Y axis, a distance the distance S3 and the distance S4 do not experience change in the straightness. Therefore, the offset OF2 does not include the component of the straightness.

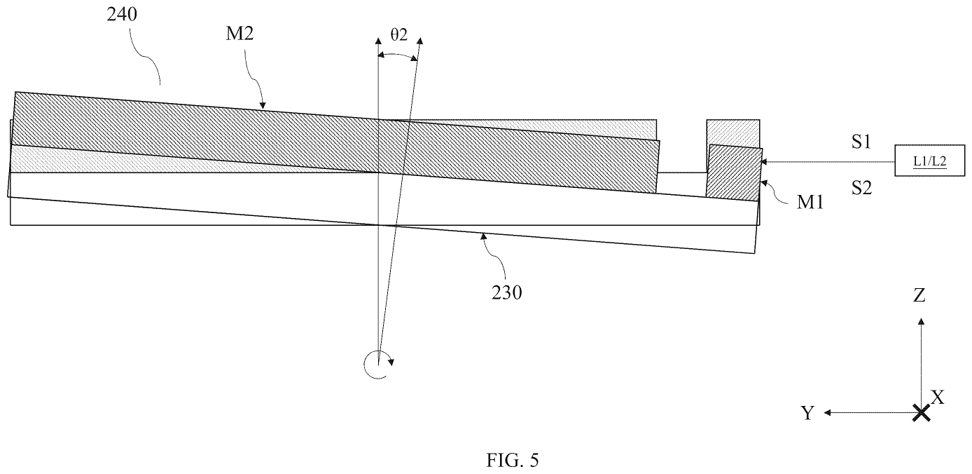

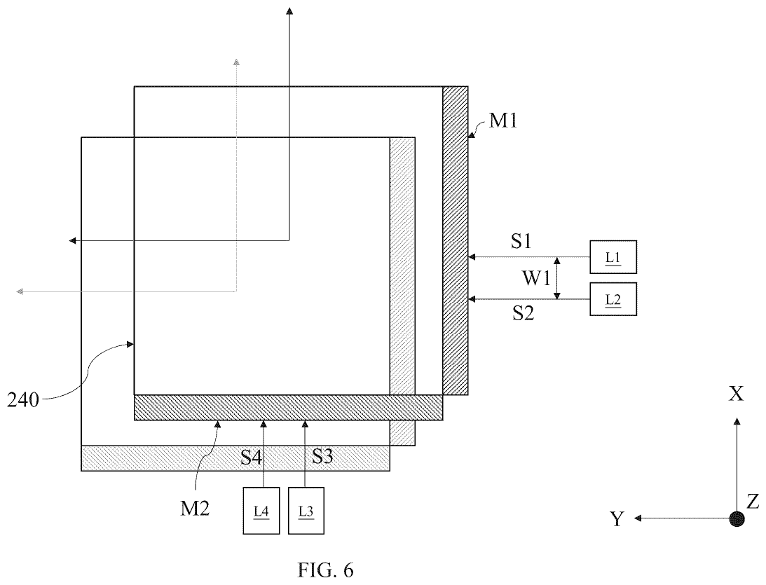

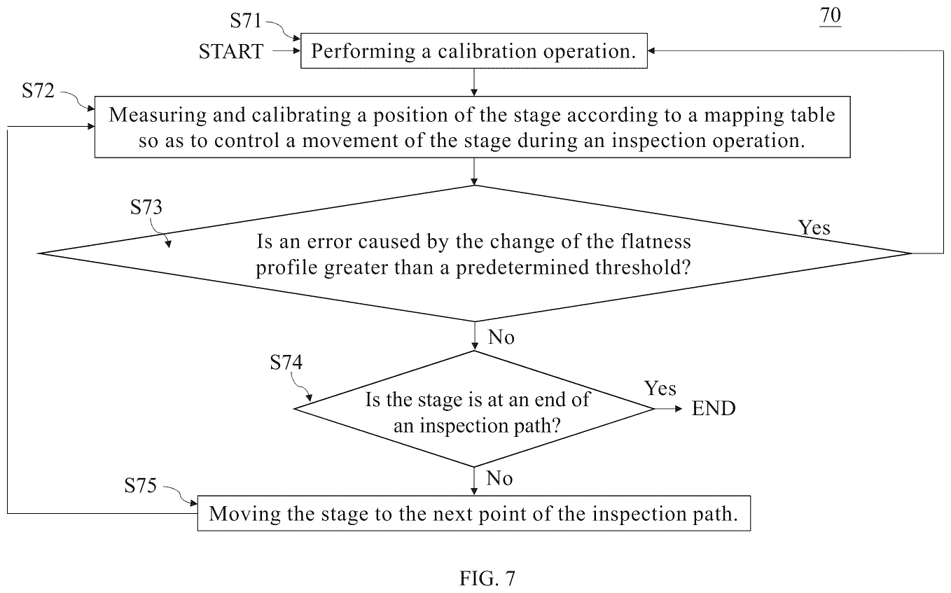

FIG. 7 is a flowchart of a position measurement method 70 according to some embodiments of the present disclosure. The position measurement method 70 includes operations S71, S72, S73, S74, and S75. In some embodiments, the position measurement method 70 is performed by the position measure device 10. To facilitate understanding, the position measurement method 70 is described according to the operations of the position measurement device 10 but not intended to be limiting.

In operation S71, a calibration operation is performed by the position measurement device 10. As mentioned above, the position measurement device 10 may have intrinsic nonlinearities, and the calibration operation is performed to calibrate the intrinsic nonlinearities. In some embodiments, in the calibration operation, the stage 200 is free of bearing a wafer.

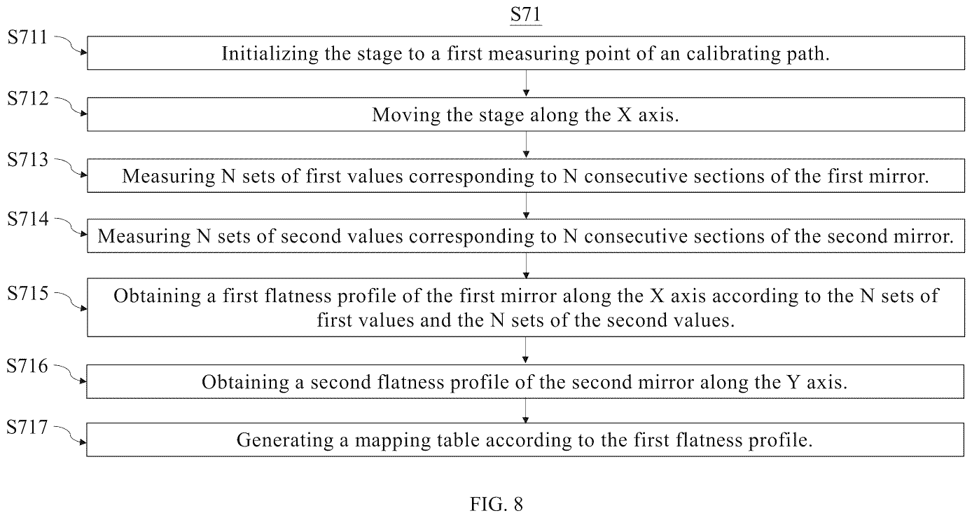

In some embodiments, the operation S71 is performed to obtain the flatness profile FP1(x) and/or the flatness profile FP2(y). The flatness profile FP1(x) includes N segments which respectively represents the flatness of N consecutive sections of the reflective surface of the mirror M1 along the X axis, in which N is a positive integer greater than 1. Similarly, the flatness profile FP2(y) includes a plurality of segments representing the flatness of a plurality of consecutive sections of the reflective surface of the mirror M2 along the Y axis, respectively. In some embodiments, each section of the reflective surface of the mirror M1 has the same length along the X axis, and each section of the reflective surface of the mirror M2 has the same length along the Y axis. The operation S71 includes operations S711, S712, S713, S714, S715, S716, and S717 (shown in FIG. 8).

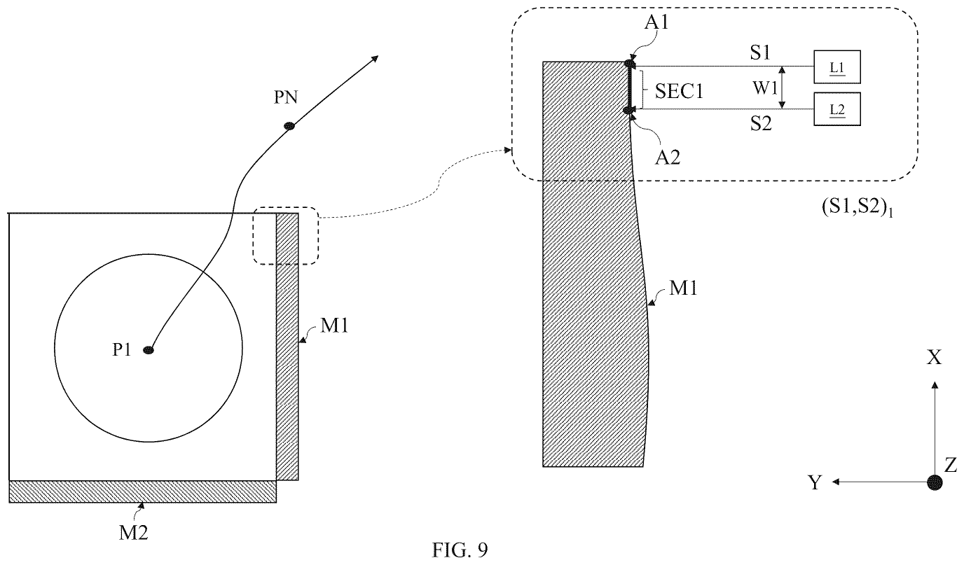

In operation S711, the stage 200 is initialized. Please refer to FIG. 9, the stage 200 is initialized to a measuring point P1 of a calibration path.

In operation S712, the stage 200 is moved along the calibration path. In some embodiments, the calibration path is a straight line along the X axis, in such path, the laser interferometers L3-L4 can have less error. The calibration path includes a plurality of measuring points P1 to PN, and the pitch W1 between the laser interferometers L1-L2 is equal to a distance between the two adjacent measuring points of the calibration path along the X axis.

In operation S713, as the stage 200 moves, the laser interferometers L1-L2 measures a set of distances S1 and S2 between the laser interferometers L1-L2 and the mirror M1 each time when the stage 200 reaches a measuring point of the N measuring points P1 to PN on the calibration path. For example, when the stage 200 is at the measuring point PM of the measuring points P1 to PN, the laser interferometer L1 and the laser interferometer L2 measure the distance S1 and the distance S2, respectively, in which M is a positive integer less than or equal to N. For ease of understanding, a set of the distance S1 and the distance S2 measured at the measuring point PM is also referred an Mth set of first values, which is designated with (S1, S2)_{M}. The Mth set of first values (S1, S2)_{M} corresponds to the Mth segment of the flatness profile FP1(x).

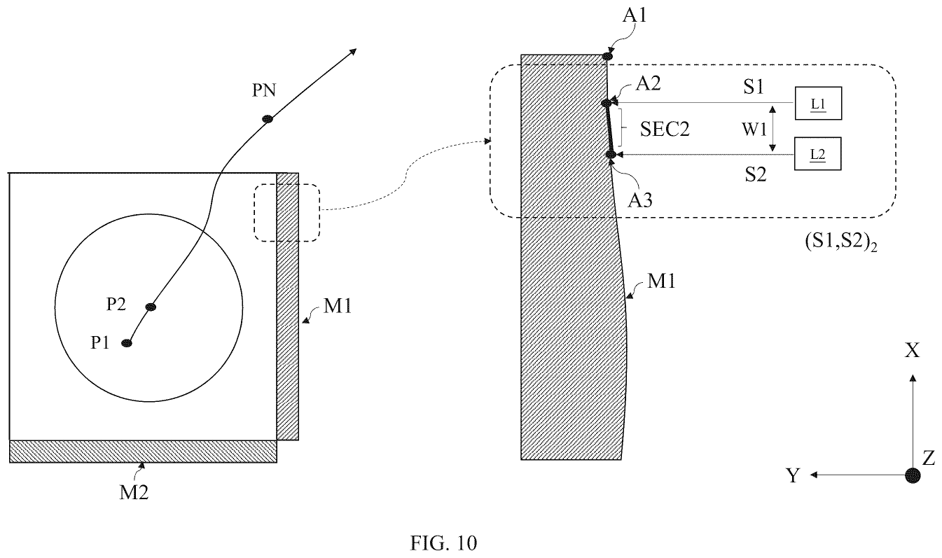

Specifically, as shown in FIG. 9, the stage 200 is moved from the first point P1 to the Nth point PN in the calibration operation. When the stage 200 arrives the first measuring point P1 (i.e., M=1), the laser interferometer L1 measures the distance S1 with respect to a first point A1 of the mirror M1, and the laser interferometer L2 measure the distance S2 with respect to a second point A2 of the mirror M1. In such case, the set of distance S1 and S2 measures at the measuring point P1 is corresponding to a first section SEC1 of the mirror M1, and is designated with the first set of first values (S1, S2)₁. Further, as shown in FIG. 10, when the stage 200 arrives the measuring point P2 (i.e., M=2), the laser interferometer L1 measures the distance S1 with respect to the second point A2 of the mirror M1, and the laser interferometer L2 measure the distance S2 with respect to a third point A3 of the mirror M1. In such case, the set of distance S1 and S2 measured at the measuring point P2 is corresponding to a second section SEC2 of the mirror M1, and is designated with the second set of first values (S1, S2)₂. The measurement would repeat N times as the stage 200 moves from the measuring point P1 to the measuring point PN.

In operation S714, as the stage 200 moves, the laser interferometers L3-L4 also measures a set of distances S3 and S4 between the laser interferometers L3-L4 and the mirror M2 each time when the stage 200 reaches a measuring point of the N measuring points P1 to PN on the calibration path. For example, when the stage 200 is at the point PM, the laser interferometer L3 and the laser interferometer L4 measure the distance S3 and the distance S4, respectively. For ease of understanding, a set of the distance S3 and the distance S4 at the point PM is also referred an Mth set of second values, which is designated with (S3, S4)_{M}. The Mth set of second values (S3, S4)_{M} corresponds to the Mth segment of the flatness profile FP2(y).

In operation S715, the flatness profile FP1(x) is obtained according to N sets of first values and N sets of second values. The flatness profile FP1(x) can be expressed by the following equation (1).

$$FP 1 ( x ) = x \cdot D 2 + {\sum }_{M = 1}^{M = X} [ {( S 2 - S 1 )}_{M} - {( S 4 - S 3 )}_{M} ] . \qquad Equation ( 1 )$$

In the equation (1), (S2−S1)_{M} represents an Mth first offset between the distance S2 and the distance S1 of the Mth set of first value (S1, S2)_{M}; (S3−S4)_{M} represents an Mth second offset between the distance S4 and the distance S3 of the Mth set of second value (S3, S4)_{M}; Σ(S2−S1)_{M} represents a first accumulated value by accumulating the M first offsets; Σ(S4−S3)_{M} represents a second accumulated value by accumulating the M second offsets. It should be noted that the component of flatness profile FP1(x) cannot be measured directly and independently, because the information of all nonlinearities mixes together and hides in the measured distance S1−S4. With the equation (1), the flatness profile FP1(x) can be extracted from the measured distance S1−S4, and the nonlinearities caused by the Yaw rotation, the roll rotation, and the straightness of the stage 200 can be eliminate.

In operation S716, the flatness profile FP2(y) is obtained according to N sets of first values and N sets of second values. In some embodiments, the stage 200 is moved along another calibration path for measuring the N sets of first values and the second values, in which the another calibration path is a straight line parallel to the Y axis. The operation to obtain the flatness profile FP2(y) is similar to the operation to obtain the flatness profile FP1(x) and omitted for the sake of brevity.

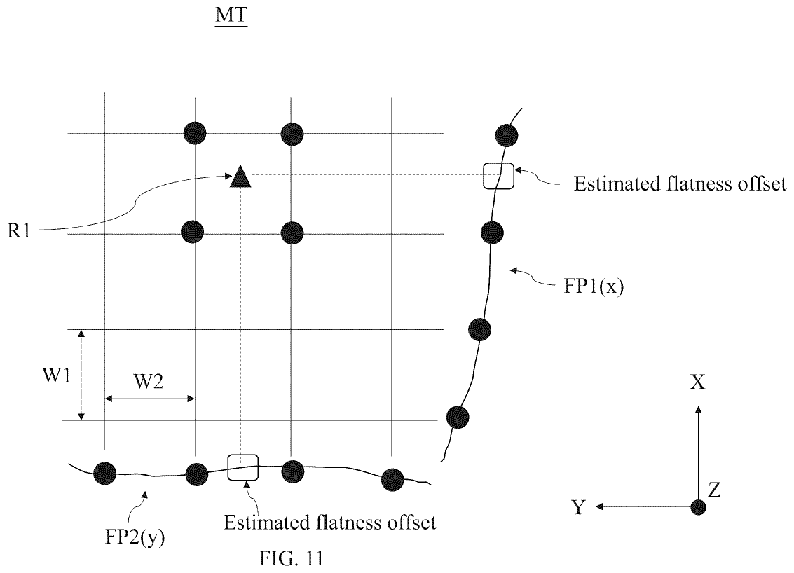

In operation S717, a mapping table MT (shown in FIG. 11) is generated according to the flatness profile FP1(x). In some embodiments, the mapping table MT is generated further according to the flatness profile FP2(y). More specifically, the mapping table MT includes correspondences between the position of the stage 200 and the corresponding flatness of the mirrors M1-M2. As shown FIG. 11, the mapping table MT can be represented as a grid constructed of the flatness profiles FP1(x) and the flatness profile FP(y). The mapping table MT represents the flatness level of the mirrors M1-M2, and being stored in the motion controller 300.

After the calibration operation is completed, the position measurement method 70 is proceeded to the inspection operation.

In operation S72, a position of the stage 200 is measured and calibrated according to the mapping table MT so as to control a movement of the stage 200 during the inspection operation.

In some embodiments, when the stage 200 is moved along an inspection path during the inspection operation, a raw position R1 of the stage 200 is measured, and the raw position R1 of the stage 200 is calibrated according to the mapping table MT so as to obtain a calibrated position of the stage 200. For example, the raw position R1 is denoted as a solid triangle in the grid of the mapping table MT, and the raw position R1 does not touch any lines of the grid. In this situation, the flatness offset with respect to the raw position can be obtained by performing interpolation according to the mapping table MT, such as using linear interpolation. After the flatness offset with respect to the raw position is estimated, the motion controller 300 is informed to calibrate the raw position according to the estimated flatness offset. Specifically, the motion controller 300 adjusts the position of the stage 200 from the raw position to the calibrated position. In some embodiments, an offset between the calibrated position and the raw position is equal to the estimates flatness offset.

Moreover, since the mirrors M1-M2 may be deformed due to the heat generated by laser irradiation or other collisions, the nonlinearities of the position measurement device 10 present on the measurement results may be different, and the flatness profiles FP1(x) and FP2(y) may need to be updated from time to time. In order to ensure the result of the calibration operation is suitable for instant situation, the position measurement method 70 is proceeded to a determination (i.e., operation S73).

In operation S73, whether an error caused by the change of the flatness profile of the mirror M1 and/or the mirror M2 being greater than a predetermined threshold is determined by the motion controller 300. In some embodiments, the Yaw rotation around the Z axis can be measured by the laser interferometers L1-L2 and as well as the laser interferometers L3-L4. For example, the Yaw rotation YW_{XM} measured by the laser interferometers L1-L2 at the measuring point PM can be obtained from an equation (2), and the Yaw rotation YW_{YM} measured by the laser interferometers L3-L4 at the measuring point PM can be obtained from an equation (3).

$${YW}_{XM} = {( S 2 - S 1 )}_{M} - FP 1 ( x ) . \qquad Equation ( 2 )$$

$${YW}_{YM} = {( S 3 - S 4 )}_{M} - FP 2 ( y ) . \qquad Equation ( 3 )$$

As illustrated in FIG. 4, the Yaw rotation YW_{XM} measured by the laser interferometers L1-L2 should be substantially equal to the Yaw rotation YW_{YM} measured by the laser interferometers L3-L4. Therefore, if the flatness profiles FP1(x) and FP2(y) can effectively help to compensate the irregularity of the mirrors M1-M2, then the result of subtracting the Yaw rotation YW_{YM} measured by the laser interferometers L3-L4 from the Yaw rotation YW_{XM} measured by the laser interferometers L1-L2 (i.e., YW_{XM}−YW_{YM}) should be zero. However, if the mirror M1 and/or the mirror M2 has been deformed, and the flatness profiles FP1(x) and FP2(y) can no longer precisely describe the actual flatness profiles of the mirror M1 and/or the mirror M2, then the absolute difference between YW_{XM} and YW_{YM} (i.e., |YW_{XM}−YW_{YM}|) would become nonzero. Therefore, in some embodiments, the absolute difference between the yaw rotations YW_{XM} and YW_{YM} calculated by the equations (2) and (3) can be seen as the error caused by the change of the flatness profile of the mirrors at the measuring point PM.

In some embodiments, the errors caused by the change of the flatness profile of the mirrors at the N measuring point can be derived, and the average of the N errors can be used as an indicator for determining whether to perform the recalibration. For example, in the position measurement method 70, when the deformation of the mirrors M1-M2 exceeds a certain amount, the average of absolute differences will be greater than the predetermined threshold, and the position measurement method 70 is proceeded to operation S71 to perform the calibration operation again.

When the absolution difference is not greater than the predetermined threshold, the position measurement method 70 is proceeded to operation S74. In operation S74, whether the stage 200 being at the end point of the inspection path is determined by the motion controller 300. When the stage 200 arrives the end point of the inspection path, the position measurement method 70 is completed. When the stage 200 is not at the end point of the inspection path, the position measurement method 70 is proceeded to operation S75.

In operation S75, the stage 200 is moved to the next point of the inspection path. After the operation S75, the position measurement method 70 is proceeded to operation S71.

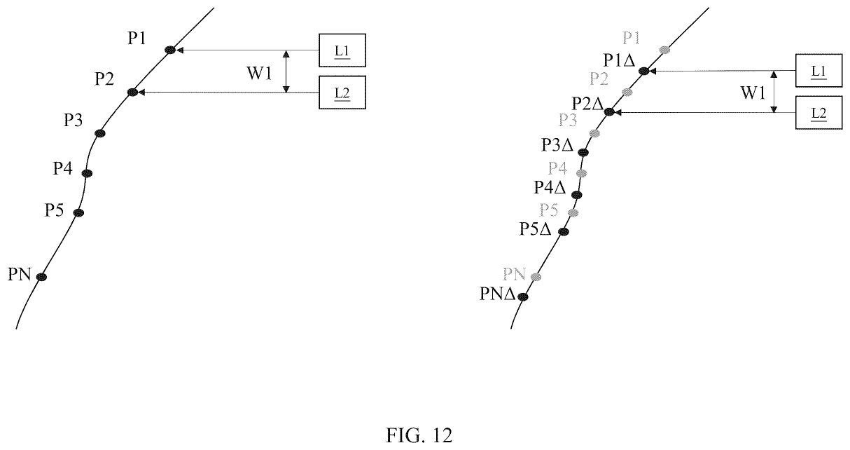

Please refer to FIG. 10. In some embodiments, the resolution of the mapping table MT is adjustable. The resolution in X axis is associated with the pitch W1 between the laser interferometers L1-L2, and the resolution in Y axis is associated with the pitch W2 between the laser interferometers L3-L4. In some embodiments, the resolution in X axis is equal to the distance between the adjacent measuring points of the calibration path. In some embodiments, the pitch W1 is equal to the pitch W2. In FIG. 11, the resolutions in X axis and Y axis are equal to the pitch W1 and the pitch W2, respectively. In some embodiments, when the position measurement device 10 needs the mapping table MT having higher resolution, the calibration path can include more measuring points, and a distance between two adjacent measuring points can be smaller than the pitch W1. For example, originally, the stage 200 is moved from the measuring point P1 to the measuring point P2, however, to increase the resolution, the stage 200 is moved from the measuring point P1 to an intermediated measuring point P1Δ instead as illustrated in FIG. 12. The distance between the measuring point and the measuring point P14 is smaller than the distance between the measuring point P1 and the measuring point P2. Similarly, measuring points P2Δ, P3Δ, P4Δ, P5Δ, . . . and PNA can be inserted in the calibration path. Therefore, the laser interferometers L1-L4 would measure more sets of the distances to build the mapping table MT so as to make the resolution of the mapping table MT finer.

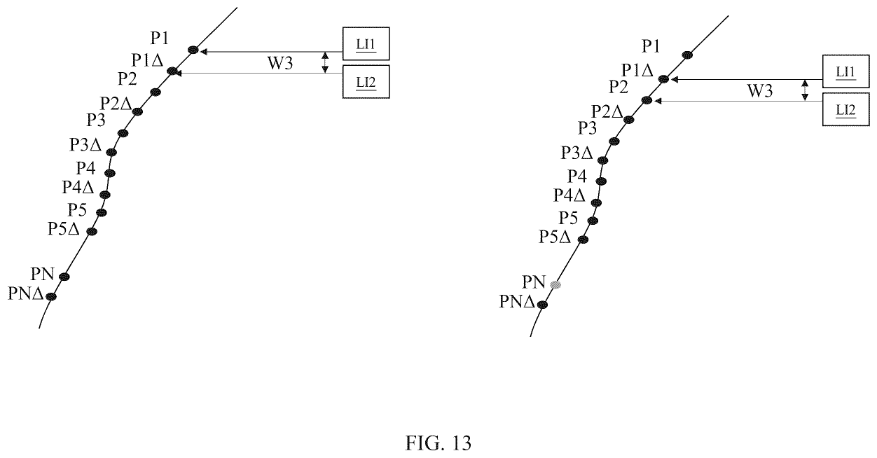

In other embodiments, the pitch W1 between laser interferometers L1-L2 and the distance between the adjacent measuring points in the calibration path are decreased to be a pitch W3 as illustrated in FIG. 13. By doing this way, the position measurement device 10 can also make the mapping table have finer resolution.

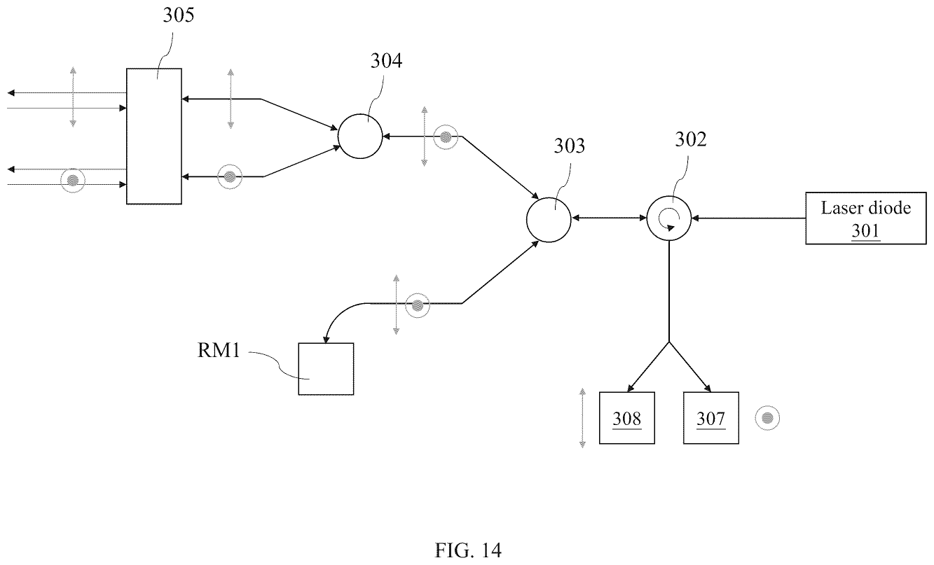

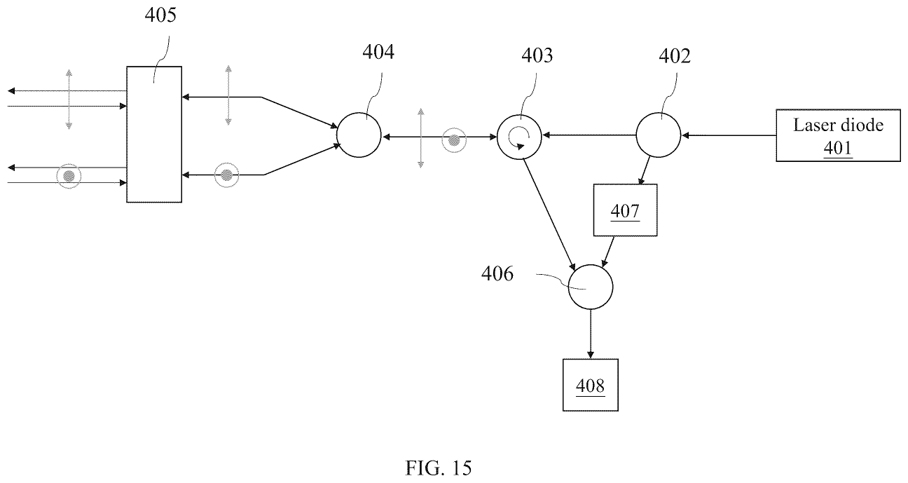

FIG. 14 and FIG. 15 are schematic diagrams of a laser interferometer according to some embodiments of the present disclosure. In some embodiments, the laser interferometers L1-L2 use the same light source, and the laser interferometers L3-L4 use the same light source.

In some embodiments, the laser interferometers L1-L2 are the same as the laser interferometers L3-L4. For the sake of brevity, FIG. 14 and FIG. 15 are described with respect to the laser interferometers L1-L2.

In FIG. 13, the laser interferometers L1-L2 includes a laser diode 301, a circulator 302, a polarization maintained coupler 303, a polarization beam splitter 304, a collimator 305, a photo detector 307, and a photo detector 308.

The photo diode 301 is configured to generate a source laser to the circulator 302. The circulator 302 is a three-port device, and configured to receive the laser at a port and emit the same at the next port. In this embodiment, the circulator 302 receives the source laser from the laser diode 301 and emit the source laser to the polarization maintained coupler 303. The polarization maintained coupler 303 divides the source laser to the polarization beam splitter 304 and the reference mirror RM1. The source laser is transmitted with vertical and horizontal polarizations. The polarization maintained coupler 303 maintains the polarizations of the source laser to the polarization beam splitter 304 and the reference mirror RM1.

The polarization beam splitter 304 divides the laser to the collimator 305 according to the polarizations. Specifically, the collimator 305 includes two channels, the polarization beam splitter 304 transmits the portion with vertical polarization (denoted with vertical double arrow) and horizontal polarization (denoted with concentric circle) to the first channel and the second channel, respectively. The collimator 305 is configured to collimate and emit the laser. The first channel of the collimator 305 is configured to be the laser interferometer L1 using the laser with vertical polarization, and the second channel of the collimator 305 is configured to be the laser interferometer L2 using the laser with horizontal polarization.

The collimator 305 is further configured to receive and transmit the reflected laser to the polarization beam splitter 304. The polarization beam splitter 304 is further configured to transmit the laser to polarization maintained coupler 303. The polarization maintained coupler 303 receives the laser from the polarization beam splitter 304 and the reference mirror RM1. The laser from the polarization beam splitter 304 interferes with the laser from the reference mirror RM1, and the polarization maintained coupler 303 transmits the interfered laser to the circulator 302. The pattern in the interfered laser includes the distance information (i.e., the distance S1 and the distance S2). The circulator 302 receive the interfered laser from the polarization maintained coupler 303 and emit the same to the photo detector 307 and the photo detector 308.

The photo detector 307 and the photo detector 308 are polarization sensitive. Specifically, the photo detector 307 is configured to capture the laser with horizontal polarization, however, the photo detector 307 barely captures the laser with vertical polarization. In contrast, the photo detector 308 is configured to capture the laser with vertical but the horizontal polarization.

In the configuration shown in FIG. 13, the laser interferometers L1-L2 share the same laser diode 301. Therefore, the number of elements in the position measurement device 10 is decreased, and the laser interferometers L1-L2 can be synchronized much easier.

In some embodiments, the position measurement device 10 does not includes reference mirror RM1, and the laser interferometers L1-L2 apply the configuration shown in FIG. 14.

In FIG. 14, the laser interferometers L1-L2 include a laser diode 401, a coupler 402, a circulator 403, a polarization beam splitter 404, a collimator 405, a coupler 406, a polarization modulator 407, and a photo detector 408.

The laser diode 401 is configured to generate a source laser to the coupler 402. The coupler 402 has two outputs and an input. The input is coupled to the laser diode 401. The first output is coupled to the circulator 403, and the second output is coupled to the polarization modulator 407. The coupler 402 is configured to transmit the source laser to the circulator 403 and the polarization modulator 407.

The circulator 403 is a three-port device, and configured to receive the laser at a port and emit the same at the next port. In this embodiment, the circulator 403 receives the laser from the coupler 402 and emit the laser to the polarization beam splitter 404.

The polarization beam splitter 404 divides the laser to the collimator 405 according to the polarizations. Similar to the collimator 305, the same as the collimator 405 includes two channels, the polarization beam splitter 404 transmits the portion with vertical polarization (denoted with vertical double arrow) and horizontal polarization (denoted with concentric circle) to the first channel and the second channel, respectively. The collimator 405 is configured to collimate and emit the laser. The first channel of the collimator 405 is configured to be the laser interferometer L1 using the laser with vertical polarization, and the second channel of the collimator 405 is configured to be the laser interferometer L2 using the laser with horizontal polarization.

The collimator 405 is further configured to receive and transmit the reflected laser to the polarization beam splitter 404. The polarization beam splitter 304 is further configured to transmit the laser to circulator 403.

The circulator 403 receive the laser from the polarization beam splitter 304 and emit the same to the coupler 406. The coupler 406 receives the laser from the circulator 403 and the polarization modulator 407. In some embodiments, the polarization modulator 407 changes the polarization of the laser to vertical polarization and horizontal polarization periodically. The laser from the circulator 403 interferes with the laser from the polarization modulator 407, and the photo detector 408 is configured to capture the interfered laser. Because the polarization of the laser from the polarization modulator 407 switches between vertical and horizontal periodically, the photo detector 408 can capture the information switching between the distance S1 and the distance S2 periodically.

In the configuration shown in FIG. 14, the laser interferometers L1-L2 share the same laser diode 401 and the same photo detector 408. Therefore, the number of elements in the position measurement device 10 is decreased, and the laser interferometers L1-L2 can be synchronized much easier.

An aspect of the present disclosure provides a position measurement method configured to measure a position of a stage. The stage includes a first mirror and a second mirror. A first interferometer and a second interferometer face the first mirror along a first axis, and a third interferometer and a fourth interferometer face the second mirror along a second axis perpendicular to the first axis. The position measurement method includes: performing a calibration operation; and measuring the position of the stage according to a mapping table so as to control movement of the stage during an inspection operation. The step of performing the calibration operation includes: moving the stage along the second axis; measuring, by the first laser interferometer and the second laser interferometer, N sets of first values corresponding to N consecutive sections of the first mirror along the second axis as the stage moves, wherein an Mth set of first values comprises a first distance between the first mirror and the first laser interferometer and a second distance between the first mirror and the second laser interferometer; measuring, by the third laser interferometer and the fourth laser interferometer, N sets of second values as the N sets of first values are measured, wherein an Mth set of second values comprises a third distance between a second mirror and the third laser interferometer and a fourth distance between the second mirror and the fourth laser interferometer; obtaining a first flatness profile of the first mirror along the second axis according to the N sets of first values and the N sets of the second values, wherein N and M are a positive integer, and M is less or equal to N; and generating the mapping table according to the first flatness profile.

The foregoing outlines features of several embodiments of the present application so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A position measurement method, configured to measure a position of a stage, wherein the stage comprises a first mirror and a second mirror, a first laser interferometer and a second laser interferometer face the first mirror along a first axis, a third laser interferometer and a fourth laser interferometer face the second mirror along a second axis perpendicular to the first axis, and the position measurement method comprising:
performing a calibration operation, comprising:
moving the stage along the second axis;
measuring, by the first laser interferometer and the second laser interferometer, N sets of first values corresponding to N consecutive sections of the first mirror along the second axis as the stage moves, wherein an Mth set of first values comprises a first distance between the first mirror and the first laser interferometer and a second distance between the first mirror and the second laser interferometer;
measuring, by the third laser interferometer and the fourth laser interferometer, N sets of second values as the N sets of first values are measured, wherein an Mth set of second values comprises a third distance between a second mirror and the third laser interferometer and a fourth distance between the second mirror and the fourth laser interferometer;
obtaining a first flatness profile of the first mirror along the second axis according to the N sets of first values and the N sets of the second values, wherein N and M are a positive integer, and M is less or equal to N; and
generating a mapping table according to the first flatness profile; and
measuring and calibrating a position of the stage according to the mapping table so as to control movement of the stage during an inspection operation.

2. The position measurement method of claim 1, wherein the first flatness profile comprises a first flatness to a Nth flatness, and the first flatness to the Nth flatness correspond to a first section to an Nth section of the N consecutive sections of the first mirror, respectively.

3. The position measurement method of claim 2, wherein the N sets of first value and the N sets of second values includes components of the first flatness profile and a Yaw rotation, wherein the step of obtaining the first flatness profile is performed to extract the first flatness profile from the N sets of first value and the N sets of second values.

4. The position measurement method of claim 2, wherein the step of obtaining the first flatness profile comprises:
obtaining an Mth first offset between the second distance and the first distance of the Mth set of first value;
obtaining an Mth second offset between the fourth distance and the third distance of the Mth set of second value;
obtaining a first accumulated values by accumulating the M first offsets;
obtaining a second accumulated value by accumulating the M second offsets;
obtaining an Mth difference between the first accumulated value and the second accumulated value; and
obtaining the Mth flatness according to the Mth difference.

5. The position measurement method of claim 4, wherein the Mth flatness is obtained by adding the Mth difference and M times of the second distance.

6. The position measurement method of claim 1, wherein the step of performing the calibration operation further comprises:
obtaining a second flatness profile of the second mirror along the first axis using the first laser interferometer, the second laser interferometer, the third laser interferometer, and the fourth laser interferometer.

7. The position measurement method of claim 6, wherein the mapping table is generated further according the second flatness profile.

8. The position measurement method of claim 6, further comprising:
determining whether an error caused by a change of the first flatness profile and the second flatness profile greater than a predetermined threshold; and
when the error is greater than the predetermined threshold, performing the calibration operation again to update the first flatness profile and the second flatness profile.

9. The position measurement method of claim 8, wherein the error is obtained by subtracting a first Yaw rotation from a second Yaw rotation, wherein the first Yaw rotation is measured by the first laser interferometer and the second laser interferometer, and the second Yaw rotation is measured by the third laser interferometer and the fourth laser interferometer.

10. The position measurement method of claim 1, the step of performing the calibration operation further comprises:
before obtaining the first flatness profile, initializing the stage to a starting point of a calibrating path.

11. The position measurement method of claim 1, wherein the N consecutive sections of the first mirror have a same length along the second axis.

12. The position measurement method of claim 1, wherein the second distance of the Mth set of second values includes contributions of a Yaw rotation around a third axis, a roll rotation around the first axis, a straightness along the second axis, and an Mth flatness of the first flatness profile,
wherein the third axis is perpendicular to the first axis and the second axis.

13. The position measurement method of claim 1, wherein the step of measuring and calibrating the position of the stage according to the mapping table comprises:
measuring a raw position of the stage when the stage is moved along an inspection path; and
calibrating the raw position of the stage according to the mapping table to obtain a calibrated position of the stage.

14. The position measurement method of claim 1, wherein the calibration operation is performed periodically.

15. The position measurement method of claim 1, wherein the calibration operation is performed in parallel to the inspection operation.
